(19) United States
(12) Patent Application Publication
(10) Pub. No.: US 2003/0057989 A1
(43) Pub. Date: Mar. 27, 2003

(54) Method of diagnosing discrete output stages via digital inputs

(76) Inventor: Stephan Rosenberg, Farmington Hills, MI (US)

Correspondence Address: KENYON & KENYON, ONE BROADWAY, NEW YORK, NY, 10004, US

(21) Appl. No.: 10/201,359

(22) Filed: Jul. 23, 2002

(30) Foreign Application Priority Data
Jul. 23, 2001 (DE) 101 35 798.2-35

(51) Int. Cl. G01R 31/26

(52) U.S. Cl. 324/765; 324/523

(57) ABSTRACT

A method of diagnosing an electric consumer using an analyzer unit is described. The electric consumer is supplied with a power supply voltage via a voltage divider. A first digital diagnostic port and a second diagnostic port of the analyzer unit are connected to the power supply voltage via the voltage divider. The diagnostic ports each detect a voltage U_{low} or a voltage U_{high}, depending on the voltage applied.

### BACKGROUND INFORMATION

For diagnosing output stages (e.g., discrete FET output stages) in control units, the voltage applied instantaneously to the output stage (drain-source voltage) is input by an analog port and converted to a digital value. Analog ports which are necessary for analyzing sensors generating analog signals are available only to a limited extent in microcontrollers (μCs). In the wake of advances in control unit generations, the number of signals to be analyzed has been increasing steadily. In today's control unit generations, the number of signals to be analyzed exceeds the number of analog/digital ports in microcontrollers required for analysis, so a choice of analog signals to be converted must be made.

U.S. Pat. No. 4,654,645 describes a detector for detecting the failure of an electric component. According to this implementation, an electric component is connected in series to a switching element and thereby defines a series circuit. A processing unit generates a control signal to trigger the switching element between an on position and an off position to control the current flowing in the series circuit. A comparator component is provided to compare the voltage at one end of the electric component with a reference voltage generated by a reference voltage generator. The comparator generates a resulting signal which corresponds to the result of the comparison operation of the comparator. The resulting signal is sent to the processing unit. The processing unit in turn detects the operating state of the series circuit by monitoring the combination of the control signal and the signal resulting from the comparison.

German Patent No. 40 12 109 describes a device for monitoring the function of an electric/electronic switching means, its connected consumers via a control, and its connecting line. At least one fault detection logic unit is connected in parallel to a switching means, a reference potential being supplied to the connecting point between the switching means and the consumer. The potentials of the input terminal and the output terminal of the switching means as well as the reference potential may be applied to the fault detection logic unit. Depending on the applied potentials, the fault detection logic unit differentiates between a short circuit to the positive pole, a load drop and a short circuit to ground as possible faults.

WO 87/07388 describes a method of checking load resistor circuits. By using this method, a plurality of load resistor circuits triggered by a common output stage may be monitored for their respective functionality. In the case of triggering and not triggering a common output stage, electric characteristic values are measured in all the load resistor circuits in an analyzer circuit and compared with preset reference values. When deviations are found, a display device is activated, and optionally also a circuit device which separates the output stage from a load resistor circuit which is recognized as nonfunctional by way of suitable switching means. Thus, the functionality of the remaining intact load resistor circuits may be ensured. If all load resistor circuits triggered by the common output stage become nonfunctional, after detection of the nonfunctional load resistor circuits, they may be separated from the common output stage to protect the output stage from an unacceptable load.

European Patent No. 0 516 633 also describes a method and a device for monitoring the function of an electric consumer. By comparing a signal that is used to trigger the consumer and an acknowledgment signal sent back to the control circuit, the function of an electric consumer triggered by the control circuit is monitored. The acknowledgment signal is influenced by an RC element connected between the power supply voltage and ground. To detect a short circuit of the consumer to ground, a short circuit to the power supply voltage or an interruption in a line between the control circuit and the consumer, at least one comparison query is issued, staggered in time to occur before, during, and after a switching event of the consumer.

### SUMMARY

Advantages achievable with an example embodiment of the present invention include, first, analyzing an electric consumer without occupying analog channels of an analyzer arrangement. Using the example embodiment according to the present invention, the analysis is performed via two digital inputs, a sufficient number of which are available on microcontrollers. The example embodiment according to the present invention makes use of analog channels on microcontrollers (μC) in a manner that uses considerably fewer resources. Instead of a microcontroller (μC), there may also be other analyzer modules, e.g., a logic array grid, an OP amplifier, or a discrete processing unit. The analog channels which are freed up by the implementation according to the present invention are thus available as inputs for sensors whose output signals may be processed only via an analog channel.

Using the example embodiment according to the present invention, output stage diagnosis becomes simpler, more favorable with regard to manufacturing costs and it also takes up much less space. The diagnostic step is implemented by using two digital inputs and a plurality of resistors. The two digital inputs are each applied to a power supply voltage, e.g., U=5 V, via a voltage divider. Therefore, the voltage at the first digital port (dia-high) is higher than that at the second digital port (dia-low). Depending on the voltage applied, the diagnostic ports detect the voltage state “low” (U_{low}<2.4 V) and the voltage state “high,” e.g., (U_{high}>3.6 V).

A complete diagnosis of the electric consumer with regard to a prevailing short circuit to ground, a short circuit to the battery voltage, or a load drop is detectable by using the connection of the digital diagnostic ports of the microcontroller (μC). The analysis is performed via two digital diagnostic inputs and the triggering signal of the electric consumer, e.g., an output stage.

In comparison with implementations or methods based on time measurements, the port query is simpler, faster, and much more reliable from the standpoint of programming as well as computer resources. In addition, electric consumers such as output stages, for example, may optionally be equipped with a diode polarity reversal protection. The diagnostic function of the three fault states mentioned above is guaranteed even when using a diode polarity reversal protection if a suitably dimensioned resistor is connected in parallel to the blocking diode.

### BRIEF DESCRIPTION OF THE DRAWING

The FIGURE illustrates the connection of two digital diagnostic ports of a microcontroller.

### DETAILED DESCRIPTION

The FIGURE illustrates an example connection of two digital diagnostic ports of a microcontroller μC. The FIGURE shows the diagnostic circuit created between a microcontroller (μC), identified with reference number 17, or an analyzer module or a logic array grid of a discrete processing unit or an operational amplifier and an electric consumer 1 in the form of a discrete output stage, for example. The output stage shown here may be part of a starter control having low voltage capability, for example.

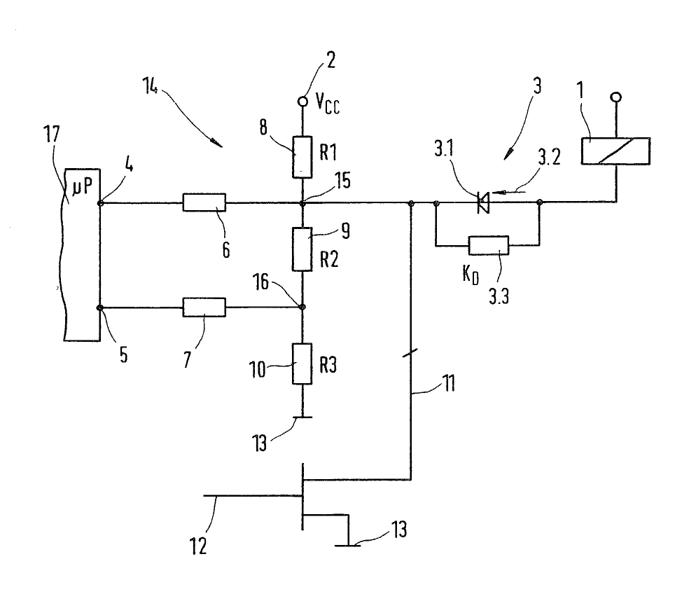

Power supply voltage V_{cc}, e.g., 5 V, is input to the load path at the electric consumer to microcontroller 17 at terminal 2. A first resistor 8 (R1) is integrated into the power line from power supply voltage 2 to a tapping point 15 for first digital diagnostic port 4. A supply lead extends from tap 15 for first digital diagnostic port 4 to first digital diagnostic port 4 of microcontroller 17, which has a first high-resistance protective resistor 6 (100K). Beneath tap 15 for first diagnostic port 4, there is a second resistor 9 (R2) in a voltage divider 14. Downstream from second resistor 9 (R2), another tapping point 16 is accommodated in voltage divider 14. A lead extends from additional tapping point 16 to second digital diagnostic port 5 of microcontroller 17 which has another protective resistor 7 (100K). According to the diagram in FIG. 1, a third resistor 10 (R3) is accommodated in voltage divider 14 beneath additional tapping point 16 to second diagnostic port 5 of microcontroller 17. Voltage divider 14 is connected to ground at position 13.

The two protective resistors 6 and 7 installed in the supply leads to digital diagnostic ports 4 and/or 5 of microcontroller 17 may be, for example, resistors of 100K, while first resistor (R1) is 4.7K and the two other resistors 9 and/or 10, (R2) and/or (R3) accommodated in voltage divider 14 may each have 14.7K.

A circuit line 11, which may be switched via a switching element (transistor), is assigned to the load path of electric consumer 1 in the form of an output stage. The output is labeled with reference number 12. A polarity reversal protection device 3 may be provided between the branch of control line 11 and the electric consumer. Polarity reversal protection device 3 includes a blocking diode 3.1 whose forward direction is in the direction of microcontroller 17. A resistor 3.3 (R_{D}) is connected in parallel with blocking diode 3.1 of polarity reversal protection device 3 and may have a resistance value of 1K47, for example.

The two digital diagnostic ports 4 and/or 5 provided on microcontroller 17 for diagnosing the condition of electric consumer 1 are connected to power supply voltage 2 (e.g., 5 V) via voltage divider 14. A higher voltage (high level) is established at first digital diagnostic port 4, while a lower voltage (low level) is established at second digital diagnostic port 5. Depending on the voltage applied, low (e.g., U_{low}<2.4 V) and high (U_{high}>3.5 V) corresponding to states “low” (0) and “high” (1) are established at the two digital diagnostic ports 4 and 5.

The correct operating state of the system is recognized by the two digital diagnostic ports 4 and/or 5 on microcontroller 17 on the basis of the load path connected to power supply voltage 2 when electric consumer 1 is not triggered. In this state, “high” states (1) are established at both digital diagnostic ports 4 and 5 of the microcontroller. If the output stage is switched to its off state by switching element 12, the two digital diagnostic ports 4 and 5 of microcontroller 17 assume “low” states (0). In both cases, microcontroller 17 determines that this is the correct operating state according to the following table. However, if electric consumer 1 is in the on state and a “high level” is recognized instead of “low” (0) at first digital diagnostic port 4, then microcontroller 17 recognizes a short circuit to power supply voltage 2.

If, when electric consumer 1 is off, however, a “low level” corresponding to a voltage <2.4 V is detected at both digital diagnostic ports, then both digital diagnostic ports 4 and 5 on microcontroller 17 assume a state (0), and microcontroller 17 recognizes the state of a short circuit to ground.

If electric consumer 1 is in the form of an output stage of a low voltage-capable starter control, for example, and a “high level” (1) is applied at first digital diagnostic port 4 and a “low level” (0) is applied at second digital diagnostic port 5, a load drop is recognized if electric consumer 1 is turned off.

Using the embodiment of a microcontroller 17 illustrated in the sole FIGURE, it is possible to perform a diagnosis on an electric consumer 1, bypassing an analog channel, because these are either not available at all on microcontrollers 17 of various designs or they are in extremely short supply. With the circuit according to FIG. 1, the state of electric consumer 1 is analyzed via two digital diagnostic ports 4, 5 on microcontroller 17 and the triggering signal of electric consumer 1. In comparison with the analog/digital converter implementation and/or method based on time measurements, it is simpler, faster, and much more reliable from the standpoint of programming as well as computer resources to query first digital diagnostic port 4 or second digital diagnostic port 5 of microcontroller 17. Optionally, a diode polarity reversal protection device (R3) may be achieved using the circuit example according to the present invention which does not limit the diagnostic capability of electric consumer 1. A suitably dimensioned resistor 3.3 (R_{D}) is to be connected in parallel with blocking diode 3.2 used in polarity reversal protection device 3.

For a computer having values of U_{H}=3.5 V and U_{L}=2.4 V with the selected resistors of (R1)=4.7K, (R2)=(R3)=14.7K, and R_{D}=1K47, this yields the following voltage levels for cases 1, 3, 4, and 5 cited here:

| | A | D_{high} | D_{low} | |
|---|---|---|---|---|
| 1) off | 0 | 1 | 1 | o.k. |
| 2) on | 1 | 0 | 0 | o.k. |
| 3) on | 1 | 1 | X | KS → U_{B} |
| 4) off | Ø | Ø | Ø | KS → GND |
| 5) off | Ø | 1 | Ø | load drop |

KS = short circuit

In the case of an electric consumer 1 being turned off, the output signal assumes a value of 0 and the digital signal “1” which corresponds to a U_{H}=3.5 V is established at digital diagnostic ports 4 and 5. According to the equation:

$$\frac{( 12 V - 0.7 V ) \times R3}{R1 + R2 + R3} > {U}_{high}$$

a voltage value of 4.87 V is established with the values indicated above, which reliably exceeds the voltage threshold for the high level=3.5 V.

The same also applies to electric consumer 1, which is turned on via the switch. In the correct state, logic signals “(0)” occur at the two digital diagnostic ports 4 and 5 of microcontroller 17, corresponding to a voltage U_{L}<2.4 V.

In the third case, however, with electric consumer 1 turned on, the voltage established at first digital diagnostic port 4 of microcontroller 17 is derived from the difference of U_{short circuit} −0.7 V which reliably exceeds the voltage threshold U_{H}=3.5 V for triggering a high level state.

In the fourth case, with electric consumer 1 turned off, a voltage U_{L} according to the following equation is established:

$${V}_{cc} \times \frac{{R}_{D} // R2 + R3}{R1 + {R}_{D} // R + R3}$$

With the values given above for R1, R2, R3, R_{D}, and V_{cc}, a low level voltage of 1.19 V is established. This is far below threshold voltage U_{L}=2.4 V for triggering a low level.

In the fifth case in which a load drop is assumed according to the preceding discussion, state 1 corresponding to voltage UH is established at first digital diagnostic port 4 when electric consumer 1 is turned off. The voltage at first digital diagnostic port 4 is described by the following equation:

$${U}_{DH} = \frac{R2 + R3}{R2 + R3 + R1} \times {V}_{cc} > {U}_{high} .$$

A voltage value of U_{high}=4.31 V, which is greater than the triggering threshold of U_{H}=3.5 V for triggering a high state at first digital diagnostic port 4, is established for the values given above.

A voltage U_{low} is established at the second digital diagnostic port 5 of microcontroller 17 according to the following equation:

$${U}_{DL} = \frac{R3}{R2 + R3 + R1} \times {V}_{cc} < {U}_{low} .$$

With the values given above, the voltage UL applied at second digital diagnostic port 5 is 2.16 V, which is lower than threshold voltage U_{L}=2.4 V. This ensures that in the “load drop” fault case discussed here, a “low” state prevails at second digital diagnostic port 5 of microcontroller 17.

What is claimed is:

1. A method of diagnosing an electric consumer using an analyzer unit, comprising:
supplying the electric consumer with a power supply voltage via a voltage divider;
connecting a first digital diagnostic port of the analyzer unit and a second diagnostic port of the analyzer unit to the power supply voltage via the voltage divider; and
detecting via the first digital diagnostic port and the second diagnostic port a voltage, depending on the voltage supplied.

2. The method according to claim 1, wherein when the electric consumer is turned on, the first digital diagnostic port and the second diagnostic port detect a voltage in a main path, and assume a high state.

3. The method according to claim 1, wherein when the electric consumer is turned on, the first digital diagnostic port and the second diagnostic port detect a voltage in a load path, and assume a low state.

4. The method according to claim 2, further comprising:
diagnosing by the analyzer unit a correct operating state of the electric consumer.

5. The method according to claim 1, further comprising:
detecting a short circuit to the power supply voltage when the electric consumer is turned on and state is “high” according to the voltage at the first digital diagnostic port of the analyzer unit.

6. The method according to claim 1, further comprising:
detecting a short circuit to ground when the electric consumer is turned off and a state is “low” according to the voltage at both the first digital diagnostic port and the second diagnostic port of the analyzer unit.

7. The method according to claim 1, further comprising:
detecting a load drop when the electric consumer is turned off and a “high” state is applied to the first digial diagnostic port and a “low” state is applied to the second diagnostic port.

8. A device for diagnosing an electric consumer, comprising:
a power supply configured to supply power supply voltage to the electric consumer via a voltage divider, the voltage divider including a first resistor for the power supply and two identical resistors;
an analyzer unit including a first digital diagnostic port and a second diagnostic port, the first digital diagnostic port and the second diagnostic port connected to the power supply via the voltage divider and a protective resistor connected upstream for each of the first digital diagnostic port and the second diagnostic port.

9. The device according to claim 8, further comprising:
a polarity reversal protection provided for the electric consumer, the polarity reversal protection including a blocking diode.

10. The device according to claim 9, further comprising:
a resistor connected in parallel with the blocking diode of the polarity reversal protection device.
